(19) United States
(12) Patent Application Publication
(10) Pub. No.: US 2020/0325304 A1
(43) Pub. Date: Oct. 15, 2020

(54) THERMOSETTING RESIN COMPOSITION AND PRINTED CIRCUIT BOARD INCLUDING THE SAME

(71) Applicant: NAN YA PLASTICS CORPORATION, Taipei (TW)

(72) Inventors: TE-CHAO LIAO, TAIPEI (TW); HAO-SHENG CHEN, TAIPEI (TW); HUNG-YI CHANG, TAIPEI (TW); CHIA-LIN LIU, TAIPEI (TW); CHIH-KAI CHANG, TAIPEI (TW)

(21) Appl. No.: 16/679,439

(22) Filed: Nov. 11, 2019

(30) Foreign Application Priority Data
Apr. 12, 2019 (TW) 108112881

(51) Int. Cl. C08K 7/18; C08K 3/22; C08K 3/36; C08K 5/03; C08K 5/3417; C08K 5/5313; C08J 5/24; H05K 1/03

(52) U.S. Cl. CPC C08K 7/18; H05K 2201/0242; C08K 3/36; C08K 5/03; C08K 5/3417; C08K 5/5313; C08J 5/24; H05K 1/0373; C08K 2003/2241; C08K 2003/2206; C08K 2003/2227; C08J 2351/08; H05K 2201/012; H05K 2201/0209; C08K 3/22

(57) ABSTRACT

A thermosetting resin composition and a printed circuit board including the same are provided. The composition adopts a thermosetting polyphenylene ether resin whose terminal functional group is a styrene and an acrylic. The thermosetting polyphenylene ether resin has an appropriate hydroxyl value to be easily cured, and the ratio of two different functional groups is between 0.5 and 1.5, for adjusting heat resistance, fluidity, and filling property. A particle diameter of 1 μm to 40 μm is added to control a dielectric constant, and after curing characteristics of high dielectric constant, low dielectric loss, high Tg, high rigidity, high flame resistance and low moisture absorption rate can be achieved.

### CROSS-REFERENCE TO RELATED PATENT APPLICATION

This application claims the benefit of priority to Taiwan Patent Application No. 108112881, filed on Apr. 12, 2019. The entire content of the above identified application is incorporated herein by reference.

Some references, which may include patents, patent applications and various publications, may be cited and discussed in the description of this disclosure. The citation and/or discussion of such references is provided merely to clarify the description of the present disclosure and is not an admission that any such reference is “prior art” to the disclosure described herein. All references cited and discussed in this specification are incorporated herein by reference in their entireties and to the same extent as if each reference was individually incorporated by reference.

### FIELD OF THE DISCLOSURE

The present disclosure relates to a thermosetting resin composition and a printed circuit board including the same, and more particularly to a thermosetting resin composition having good glue-filling property, cutting property and rigidity and a printed circuit board including the same.

### BACKGROUND OF THE DISCLOSURE

The insulating material used in the conventional printed circuit board is mainly epoxy resin, which has good insulation and chemical resistance after curing, and has an advantage of low cost. However, in recent years, high-frequency and broadband communication devices have undergone rapid development, signal transmission speed and data processing capacity have doubled, and electronic devices and electronic assemblies tend to be higher in density. The printed circuit boards have been developed to have a thinner line width, higher layer counts, thinner plate thickness, and be halogen-free. Therefore, electrical properties, water absorption, flame resistance, and dimensional stability of the epoxy resin are now insufficient.

Polyphenylene ether resin has excellent insulation, acid and alkali resistance, dielectric constant (Dk) and dielectric dissipation factor (Df), therefore, compared with epoxy resin, polyphenylene ether resin has better electrical properties and is more suitable for the requirements of circuit board insulation materials. However, since commercially available polyphenylene ether resins are mostly thermoplastic and have large molecular weight (average molecular weight >20,000), polyphenylene ether resins have poor solubility in a solvent and are not easily applied to a circuit board directly. Therefore, much effort has been in research and development to improve the above-mentioned shortcomings in order to modify the polyphenylene ether resin into a curable, more compatible, and more processable resin material, while retaining the excellent electrical properties of polyphenylene ether resin.

In the U.S. Pat. No. 7,858,726, a large molecular weight polyphenylene ether resin is converted into a small molecular weight polyphenylene ether resin by molecular weight redistribution. The solubility can be improved, but the molecular chain end is a hydroxyl group; the resin can be cured due to its polar nature, but it will cause an increase in dielectric loss. An average number of hydroxyl groups per polyphenylene ether molecule is less than 2, a ratio of the active group which can provide curing and the crosslinking density is insufficient. If the number of active groups is insufficient, the degree of crosslinking after curing is insufficient and the heat resistance is deteriorated.

The Taiwan Patent No. 1-464213 discloses a polyphenylene ether resin whose terminal is modified to an unsaturated group and which is cured together with bismaleimide to shorten a gelation time and the dielectric constant and to reduce electrical loss. Therefore, the effect of lowering dielectric constant and dielectric loss can be achieved with polyphenylene ether resin.

However, the dielectric constant and the dielectric loss tend to decrease at the same time, which is characterized by an increase in the transmission rate and a reduction in signal loss. In high-frequency applications, especially in high-frequency wireless transmission electronic products, antennas should be made of materials with high dielectric constant and low dielectric loss to reduce the area occupied by the antennas so as to meet needs of miniaturization of various electronic products.

The Taiwan Patent No. 1-499635 uses an ester hardener and a special epoxy resin as a low dielectric resin formulation to develop a resin composition having a high dielectric constant and a low dielectric loss. Although its dielectric constant can be increased to 18, its dielectric loss is still too high, about 0.006 or more, therefore it is not easy to apply to millimeter wave antennas.

The Taiwan Patent No. 1-488904 provides a carbon black material using ultrafine powder, which is added to a resin to increase a dielectric constant. However, its dielectric loss (Df) is greater than 0.005, and carbon black is prone to issues relating to electrical conduction, such that the addition is limited, and also in the process.

Polyphenylene ether structure itself contains a large amount of benzene rings, has high stability, and has better flame resistance. A use of a small molecular weight polyphenylene ether resin can improve the solubility of the ether structure, but its heat resistance is poor. If an end of the small molecular weight polyphenylene ether resin is further modified to a thermosetting polyphenylene ether resin having a specific functional group, a degree of crosslinking is improved after heat curing, and the heat resistance is also increased, thereby increasing the application space thereof.

A terminal group of the thermosetting polyphenylene ether resin may be a hydroxyl group, but a disadvantage is that a polar group is generated during the curing process, which is disadvantageous to the dielectric loss of the plate after curing, and is prone to bursting and having problems with heat resistance due to an increase in water absorption.

When the terminal group of the thermosetting polyphenylene ether resin is modified to a non-polar group (such as an alkenyl group of an unsaturated group, an alkynyl group, etc.), and then thermally cured, the curing process does not produce a polar group, and there is no polarity after curing. The base residue can lower the Df (dielectric loss) value and lower the water absorption rate, but the dielectric constant also decreases.

When the terminal group of the thermosetting polyphenylene ether resin is further modified to an acrylic group which belongs to a non-polar group, no polar group is generated during curing, and a better electrical property and a lower water absorption rate can be obtained. However, the basic structure of the acrylic body belongs to a carbon-hydrogen bond structure and belongs to a soft structure, and when the acrylic body is cured by heat, the fluidity is better. However, a disadvantage is that a stability of carbon-hydrogen bond is poor and thus easily cracked by heat, and the heat resistance is also poor.

When the terminal structure of the polyphenylene ether resin is modified to a styrene group which belongs to a non-polar group, no polar group is generated during curing, and no polar group remains after the curing, so that electrical properties and water absorption can be reduced. The styryl group has a benzene ring structure and is a hard structure, and has high structural stability and high heat resistance due to an electron resonance effect. However, the disadvantage is that when being cured by heat, a fluidity thereof is poor. Especially when the resin is applied to the multi-layer plate pressing process of thick copper (above 2 OZ), poor line filling effect is often caused by poor fluidity.

In view of the above problems, there is a need for a thermosetting resin composition which provides more non-polar unsaturated functional groups, and includes a polyphenylene ether resin. Preferably, a hardenable unsaturated reactive functional group at the end of the main chain of the polyphenylene ether resin is provided, and no polar groups exist, so that good glue-filling and cutting properties can be provided, the rigidity can be improved, and water absorption can be lowered, while maintaining a certain dielectric constant and dielectric loss.

### SUMMARY OF THE DISCLOSURE

In response to the above-referenced technical inadequacies, the present disclosure provides a thermosetting resin composition and a printed circuit board including the same

In one aspect, the present disclosure provides a printed circuit board including an insulating layer which is made of a thermosetting resin composition.

In one aspect, the present disclosure provides a thermosetting resin composition in which a main resin is a combination of a thermosetting polyphenylene ether resin including a composition of a styrene type polyphenylene ether resin and an acrylic type polyphenylene ether resin. The styrene type polyphenylene ether resin and the acrylic type polyphenylene ether resin have a certain ratio, which improves the heat resistance of the acrylic structure, and also the fluidity of the styrene structure, and can satisfy both fluidity and heat resistance.

In one aspect, the present disclosure provides a high dielectric constant thermosetting resin composition which has a high dielectric constant and can control dielectric loss in a suitable range of millimeter wave high frequency (i.e., dielectric loss <0.003), achieving both high dielectric constant and low dielectric loss.

In one aspect, the present disclosure provides a resin composition based on the above thermosetting polyphenylene ether resin, including: (a) a thermosetting polyphenylene ether resin which accounts for 15% to 35% by weight of a solid content of the thermosetting resin composition, wherein the thermosetting polyphenylene ether resin includes a styrene type polyphenylene ether resin and an acrylic type polyphenylene ether resin, wherein the ratio of the styrene type polyphenylene ether resin to the acrylic type polyphenylene ether resin is 1:0.5 to 1:1.5, (b) a ceramic powder which accounts for 30% to 70% by weight of the solid content of the thermosetting resin composition, (c) a flame retardant which accounts for 5% to 15% by weight of the solid content of the thermosetting resin composition, (d) a crosslinking agent which accounts for 5% to 20% by weight of the solid content of the thermosetting resin composition, (e) a composite crosslinking initiator which accounts for 0.1% to 3% by weight of the solid content of the thermosetting resin composition.

In addition to the improvement of the physical properties listed above, the substrate processability is also improved, including low temperature press processing, and prepreg cutting, etc. A copper foil substrate formed by curing the thermosetting resin composition of the present disclosure has better rigidity, and a prepreg thereof is not so soft as to make cutting difficult. Therefore, there is no need to change tools frequently during production that increases the cost, and is advantageous in applications requiring multi-layer printed circuit boards such as servers.

In one aspect, the present disclosure provides a resin composition described above. The resin composition is applied to a semi-cured film for a printed circuit board, a cured sheet, a copper foil substrate which is pressed against a copper foil after being impregnated with a glass cloth, and a circuit board made of the copper foil substrate. The resin composition has good filling properties and cutting properties. Since the composition contains the above-mentioned interlaced thermosetting polyphenylene ether resin, properties after curing are characterized by high dielectric constant, low dielectric loss, high Tg, high rigidity, high flame resistance and low moisture absorption rate. Moreover, the solubility of solvent is good, and the compatibility with other resins is excellent, so that the advantages of the thermosetting polyphenylene ether resin composition are fully exhibited, and the printed circuit board product can be improved. The curing composition has excellent electrical properties of dielectric constant (Dk) of 3.5 to 10.0 and dielectric loss (Df) of <0.0030 at a frequency of 10 GHz, and also has a glass transition temperature (Tg) of more than 200° C. and 288° C. resistant solder with heat resistance more than 600 seconds.

Therefore, one of the beneficial effects of the present disclosure is that the thermosetting resin composition and the printed circuit board provided by the present disclosure can maintain a certain dielectric constant by technical feature of “ceramic powder of a specific composition ratio” so that the thermosetting resin composition has good physical properties such as glass transition temperature (Tg), rigidity and fluidity while maintaining a certain dielectric constant and dielectric loss. Accordingly, the thermosetting resin composition has excellent glue-filling properties and cutting properties in the process.

These and other aspects of the present disclosure will become apparent from the following description of the embodiment taken in conjunction with the following drawings and their captions, although variations and modifications therein may be affected without departing from the spirit and scope of the novel concepts of the disclosure.

### DETAILED DESCRIPTION OF THE EXEMPLARY EMBODIMENTS

The present disclosure is more particularly described in the following examples that are intended as illustrative only since numerous modifications and variations therein will be apparent to those skilled in the art. Like numbers in the drawings indicate like components throughout the views. As used in the description herein and throughout the claims that follow, unless the context clearly dictates otherwise, the meaning of “a”, “an”, and “the” includes plural reference, and the meaning of “in” includes “in” and “on”. Titles or subtitles can be used herein for the convenience of a reader, which shall have no influence on the scope of the present disclosure.

The terms used herein generally have their ordinary meanings in the art. In the case of conflict, the present document, including any definitions given herein, will prevail. The same thing can be expressed in more than one way. Alternative language and synonyms can be used for any term(s) discussed herein, and no special significance is to be placed upon whether a term is elaborated or discussed herein. A recital of one or more synonyms does not exclude the use of other synonyms. The use of examples anywhere in this specification including examples of any terms is illustrative only, and in no way limits the scope and meaning of the present disclosure or of any exemplified term. Likewise, the present disclosure is not limited to various embodiments given herein. Numbering terms such as “first”, “second” or “third” can be used to describe various components, signals or the like, which are for distinguishing one component/signal from another one only, and are not intended to, nor should be construed to impose any substantive limitations on the components, signals or the like.

A thermosetting polyphenylene ether resin disclosed in the present disclosure is a composition having a terminal group having a styrene type polyphenylene ether and a terminal acrylic type polyphenylene ether. The structure of the styrene-type polyphenylene ether is shown in structural formula (A):

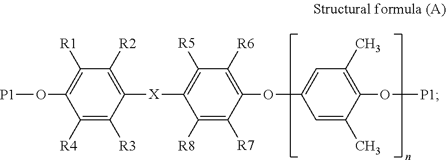

R1 to R8 are independently selected from the group consisting of allyl, hydrogen and C1-C6 alkyl;

X is selected from the group consisting of oxygen atoms:

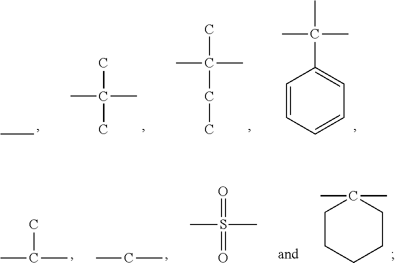

P1 is a styrene group

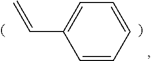

and n is an integer of 1 to 99.

The acrylic type polyphenylene ether is represented by the structural formula (B):

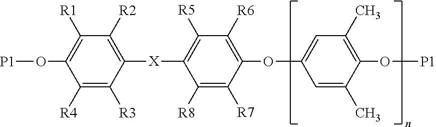

R1 to R8 are independently selected from the group consisting of allyl, hydrogen and C1-C6 alkyl;

X is selected from the group consisting of oxygen atoms:

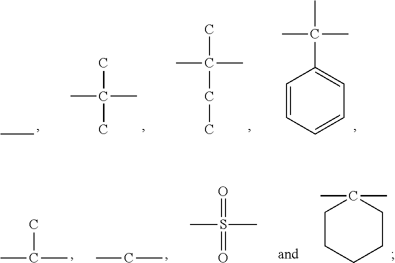

P2 is a styrene group

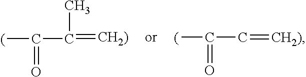

and n is an integer of 1 to 99;

There are two methods of manufacturing the thermosetting polyphenylene ether resin of the present disclosure, but not limited to the two methods. The first one is oxidative polymerization, which is composed of 2,6-dimethyl phenol (2,6-DMP for short) and oxygen (O₂) or air in the presence of a coordinating complex catalyst formed by an organic solvent and copper and an amine via carbon and oxygen atoms C—O. Further, 2,6-DMP can also be copolymerized with a phenol having a functional group to achieve a modification effect. The polyphenylene ether resin obtained by the oxidative polymerization method still has a certain number of hydroxyl groups at the end of the molecular chain, and can further impart different reactive functional groups by terminal grafting reaction.

The second method is to cleave the unfunctionalized higher molecular weight polyphenylene ether resin into a lower molecular weight polyphenylene ether by cleavage reaction of phenol and peroxide. The polyphenylene ether resin obtained by the cleavage method still has a certain number of hydroxyl groups at the end of the molecular chain, and can further impart different reactive functional groups by terminal grafting reaction; or by passing different functional diphenols, the lower molecular weight polyphenylene ether has different reactive functional groups.

In the method for manufacturing the thermosetting polyphenylene ether resin of the present disclosure, the hydroxyl group at the terminal of the molecular chain of the polyphenylene ether resin is further graft-modified. The grafting reaction mechanism is carried out based on nucleophilic substitution. In certain embodiments, the terminal hydroxyl group of the small molecular weight polyphenylene ether resin is first sodium-salted or potassium-salted to form a terminal phenoxide.

Since the terminal phenoxide has high reactivity, it can react with a monomer such as a halide, an acid halide or an acid anhydride. In a specific embodiment of the present disclosure, an acidic monomer such as a halide, an acid halide or an acid anhydride having an unsaturated active group (such as an alkenyl group or an alkynyl group) is introduced as a terminal graft in the presence of a phase transfer catalyst. After the grafting reaction, the residue of the above monomer is attached to the oxygen atom at the end of the polyphenylene ether main chain to form the interlaced thermosetting polyphenylene ether resin of the present disclosure.

The resin composition provided by the present disclosure based on the above thermosetting polyphenylene ether resin, including: (a) a thermosetting polyphenylene ether resin which accounts for 15% to 35% by weight of a solid content of the thermosetting resin composition, wherein the thermosetting polyphenylene ether resin includes a styrene type polyphenylene ether resin and an acrylic type polyphenylene ether resin, wherein the ratio of the styrene type polyphenylene ether resin to the acrylic type polyphenylene ether resin is 1:0.5 to 1:1.5, (b) a ceramic powder which accounts for 30% to 70% by weight of the solid content of the thermosetting resin composition, (c) a flame retardant which accounts for 5% to 15% by weight of the solid content of the thermosetting resin composition, (d) a crosslinking agent which accounts for 5% to 20% by weight of the solid content of the thermosetting resin composition, and (e) a composite crosslinking initiator which accounts for 0.1% to 3% by weight of the solid content of the thermosetting resin composition. The function, mixing ratio and structure of each component are as follows:

(a) The thermosetting polyphenylene ether resin, which accounts for 40% to 60% by weight of the solid content of the thermosetting resin composition, refers to the polyphenylene ether resin of the following structural formula (A) and structural formula (B):

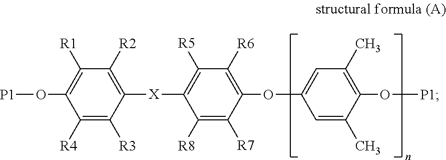

R1 to R8 are independently selected from the group consisting of allyl, hydrogen and C1-C6 alkyl;

X is selected from the group consisting of oxygen atoms:

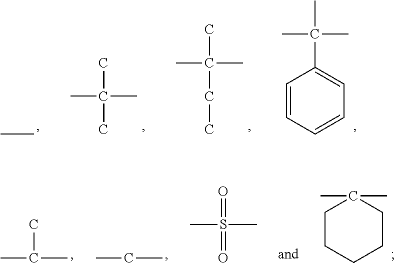

P1 is a styrene group

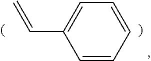

and n is an integer of 1 to 99.

The acrylic type polyphenylene ether is represented by the structural formula (B):

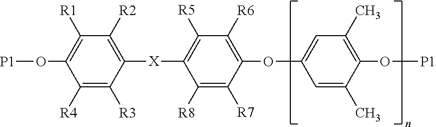

R1 to R8 are independently selected from the group consisting of allyl, hydrogen and C1-C6 alkyl;

X is selected from the group consisting of oxygen atoms:

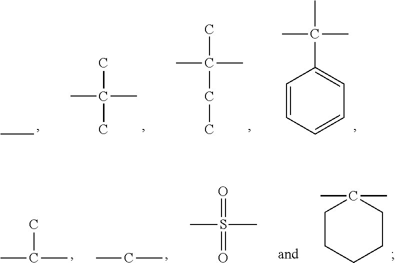

P2 is a styrene group

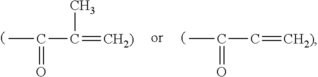

and n is an integer of 1 to 99;

The thermosetting polyphenylene ether resin of the present disclosure includes a styrene type polyphenylene ether resin having a styryl group at the end and an acrylic type polyphenylene ether resin having an acrylic group at the end. The ratio of the styrene type polyphenylene ether resin to the acrylic type polyphenylene ether resin is from 1:0.5 to 1:1.5, preferably between 1:0.75 and 1:1.25.

The thermosetting polyphenylene ether resin of the present disclosure preferably has a number average molecular weight more than (Mn) 1,000 and less than 25,000, preferably more than 2,000 and less than 10,000, and a preferable physical property such as a glass transition temperature (Tg), a dielectric constant, and a dielectric loss can be obtained.

The thermosetting polyphenylene ether resin of the present disclosure has at least one or more unsaturated reactive functional groups at its terminal end, and the amount of terminal grafting functional groups can be judged by measuring the hydroxyl value. The hydroxyl value measurement is measured according to the Chinese National Standard (CNS) 6681, and the method is to prepare a pyridine solution of 25 vol. % anhydrous acetic anhydride for preparing an acetylation reagent. Several grams of a sample to be tested and 5 ml of the acetylation reagent are finely weighed after mixing and heating to completely dissolve the sample, phenolphthalein is added as an indicator and calibrated with a 0.5 N potassium hydroxide ethanol solution.

The thermosetting polyphenylene ether resin of the present disclosure preferably has a hydroxyl value less than 3.0 mgKOH/g, more preferably less than 2.0 mgKOH/g, and a hydroxyl value of at least 0.001 mgKOH/g can ensure that sufficient functional groups are involved in the reaction to obtain better physical properties such as glass transition temperature (Tg) and heat resistance. When the hydroxyl value is greater than 10.0 mgKOH/g, the number of functional groups grafted at the end is insufficient, which may cause the physical properties such as glass transition temperature (Tg) or heat resistance to be unsatisfactory after curing, and a blasting situation often occurs after platen.

The thermosetting polyphenylene ether resin of the present disclosure has a lower hydroxyl value, which means that the polyphenylene ether resin used in the formula has sufficient functional groups to participate in the reaction, so that a platen temperature of the composition can be lower, and the required physical properties can be achieved at temperature of 150° C. to 200° C.

(b) The ceramic powder, which accounts for 30 to 70% by weight of the thermosetting resin composition, can not only improve a mechanical strength and a dimensional stability of the resin composition after curing, but, more important, to increase the dielectric constant of a sheet by the selection of the inorganic powder.

The ceramic powder is selected from one or any combination of spherical or irregular silicon dioxide (SiO₂), titanium dioxide (TiO₂), alumina (Al₂O₃), boron nitride (BN), tantalum carbide (SiC), aluminum nitride (AlN), magnesium oxide (MgO), calcium carbonate (CaCO₃), boron oxide (B₂O₃), Strontium titanate (SrTiO₃), barium titanate (BaTiO₃), calcium titanate (CaTiO₃), magnesium titanate (2MgO.TiO₂), magnesium borate (Mg₂B₂O₅), magnesium sulfate (MgSO₄.7H₂O), and cerium oxide (CeO₂).

In one embodiment, the ceramic powder can be selected from one or any combination of silicon dioxide (SiO2), titanium dioxide (TiO2), strontium titanate (SrTiO3), barium titanate (BaTiO3), and calcium titanate (CaTiO3).

Intrinsic dielectric properties of ceramic powder affect the dielectric constant Dk of the sheet. The ceramic powder commonly used for copper foil substrates is shown in Table 1 below.

TABLE 1
intrinsic dielectric constant of commonly used ceramic powder

| Ceramic powder | Dielectric constant (Dk) |
|---|---|
| Silicon dioxide | 4.2 |
| Titanium dioxide | 80 |
| Zirconium dioxide | 25 |
| Aluminium oxide | 10 |
| Aluminium nitride | 8.5 |
| Magnesium oxide | 9.6 |
| Strontium titanate | 350 |
| Barium titanate | 3,000 |
| Calcium titanate | 200 |

Since each ceramic powder has its intrinsic dielectric constant, dielectric loss and thermal conductivity, the dielectric constant can be adjusted by mixing different kinds and different proportions of ceramic powder.

Adjustment of a mixing ratio of the dielectric constant (Dk), referring to the theoretical basis of H. Looyenga, Physica, 31, 401-406, 1965, can be estimated by using the following formula 1:

Dk₍ₘᵢₓ₎^{1/3}=V₁(Dk₁)^{1/3}+V₂(Dk₂)^{1/3}+V₃(Dk₃)^{1/3}+(1−V₁−V₂−V₃)(Dkᵣₑₛᵢₙ)^{1/3}; (Formula 1)

V1-V3 are the volume fractions of ceramic powder, Dk₁, Dk₂, Dk₃, Dkᵣₑₛᵢₙ refer to the intrinsic dielectric constant of the ceramic powder, and Dkᵣₑₛᵢₙ is the intrinsic dielectric constant of the resin. It can be seen from the above formula 1 that the Dk value is related to the volume fraction of the high dielectric ceramic powder added, and the dielectric constant varies depending on the ratio of the added components. That is to say, in the present disclosure, by selecting the ceramic powder and adjusting the volume ratio of the ceramic powder, an effect of regulating the dielectric constant of the thermosetting resin composition can be achieved. In general, the thermosetting resin composition preferably has the dielectric constant of 3 to 12.

In the present embodiment, the ceramic powder accounts for 30% to 70% by weight of the solid content of the thermosetting resin composition.

However, the particle diameter and particle shape of the ceramic powders also affect the actual dielectric constant. Therefore, after continuous experimentation and verification, the particle diameter of the ceramic powder is preferably from 0.5 μm to 50 μm, and more preferably from 1 μm to 40 μm. If the particle diameter exceeds 50 μm, an uniformity of dispersion in the sheet is poor, and the dielectric constant Dk may not be uniform. When the particle diameter is less than 1 μm and a surface area is too large, OH group adsorbed on the surface excessively affects the electrical properties of the sheet. When the specific surface area is too large, excessive viscosity is easily caused during formulation processing. The shape of the particle is preferably spherical or irregularly broken.

In addition to the particle diameter, purity of the ceramic powder also affects electrical properties of a board. If the purity is insufficient, the electrical properties of the sheet will be poor, and especially, the dielectric loss (Df) will increase to 0.004 or more. If the purity is extremely high, although the electrical properties of the sheet are positive, the price of the ceramic powder is relatively expensive, and the application and the addition ratio are limited. Therefore, practically, the preferred purity is 99.1 to 99.9% by weight.

(c) Flame retardant, which accounts for 5 to 15% by weight of the thermosetting resin composition, includes bromine and phosphorus flame retardants. The bromine flame retardant may be commercially available from Albemarle Corporation under the trade names Saytex BT 93 W (ethylene bistetrabromophthalimide) flame retardant, Saytex BT, 93Saytex 120 (tetradecabromodiphenoxy benzene) flame retardant, Saytex 8010 (Ethane-1,2-bis(pentabromophenyl)) flame retardant or Saytex 102 (decabromo diphenoxy oxide) flame retardant.

The phosphorus flame retardant is selected from phosphates such as triphenyl phosphate (TPP), resorcinol diphosphate (RDP), bisphenol A bis (diphenyl) phosphate (BPAPP), bisphenol A bis (dimethyl) phosphate (BBC), resorcinol diphosphate (CR-733S), resorcinol-bis(di-2,6-dimethylphenyl phosphate) (PX-200); is selected from phosphazene such as polybis(phenoxy)phosphazene (SPB-100), ammonium polyphosphates, melamine polyphosphates, and melamine cyanurate, and aluminium hypophosphite (OP935); is selected from one or any combination of flame retardant containing 9,10-dihydro-9-oxo-10-phosphaphenanthrene-10-oxide (DOPO), such as DOPO (e.g., structural formula (C)), DOPO-HQ (e.g., structural formula (D), double DOPO derived structure (such as structural formula E), and the like.

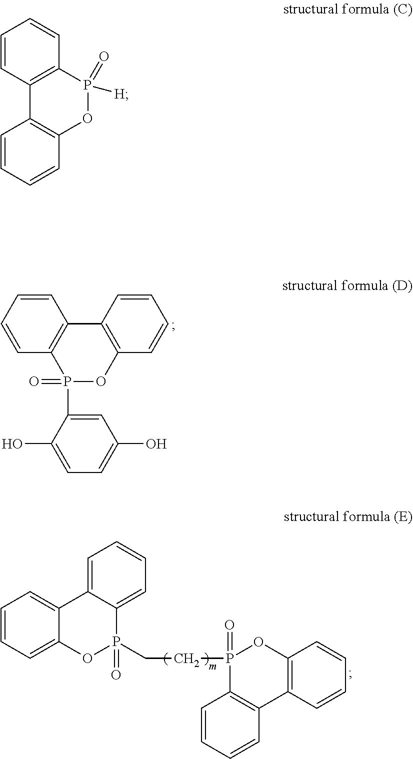

and m is an integer of 1 to 4.

The flame retardant may be selected from one or any combination of the above, and when the above flame retardant is added to the polyphenylene ether resin, the glass transition temperature of the bromine flame retardant is higher than that of the phosphorus flame retardant.

(d) The crosslinking agent which accounts for 5% to 20% by weight of the solid content of the resin composition is used to improve a degree of crosslinking of the thermosetting resin, adjust rigidity, toughness and processability of the board. The crosslinking agent is selected from one or any combination of 1,3,5-triallyl cyanurate (TAC), triallyl isocyanurate (TRIC), trimethallyl isocyanurate (TPAIC), divinylbenzene, and divinylbenzene and 1,2,4-triallyl trimellitate.

(e) The double crosslinking initiator, often an organic peroxide, which accounts for 0.1% to 3% by weight of the solid content of the resin composition, is used to accelerate crosslinking reactions at various temperatures. When the resin composition of the present disclosure is heated, at a specific temperature, the initiator decomposes to form a radical, and initiation of radical crosslinking polymerization is initiated. As temperature increases, the peroxide will be consumed faster. Therefore, there is a problem of compatibility between the peroxide and the resin composition. If the decomposition temperature of the peroxide is lower than the activation energy of the polymerization reaction, a problem of insufficient crosslinking degree may occur.

The thermosetting resin composition disclosed in the present disclosure is prepared by mixing a styrene polyphenylene ether resin and an acrylic polyphenylene ether resin in a certain ratio. Reaction activation energy of styryl group and acryl group is different. Therefore, a double crosslinking initiator is required to initiate the reaction to achieve the best physical properties. The initiator is mixed according to the ratio of the two resins, and a degree of crosslinking is the most complete.

The organic peroxide is usually selected from tert-butyl cumyl peroxide, dicumyl peroxide (DCP), benzammonium peroxide (BPO), 2,5-dimethyl-2,5-bis(tert-butylperoxy hexane, 2,5-dimethyl-2,5-di(tert-butylperoxy)hexyne or 1,1-di(tert-butylperoxy)-3,3,5-trimethyl cyclohexane, cumene hydroperoxide, and the like.

The double crosslinking initiator disclosed in the present disclosure preferably has a proportion of active oxygen contained in the peroxide of more than 5%.

The double crosslinking initiator disclosed in the present disclosure refers to a combination of a plurality of crosslinking initiators based on one hour half-life temperature of peroxide, so that the thermosetting resin composition of the present disclosure can be heated and cured. At different temperature stages, a multiple crosslinking reaction is initiated by the double crosslinking initiator to allow the resin composition to be crosslinked more completely, thus obtaining better heat resistance and physical properties.

The double crosslinking initiator of the present disclosure may be selected from one or any combination of dicumyl peroxide (reactive oxygen: 5.86%, 1 hour half-life temperature: 137° C.), 1,4 di-tert-butylperoxyisopropyl benzene (reactive oxygen: 9.17%, 1 hour half-life temperature: 139° C.), 2,5-dimethyl-2,5-di(tert-butylperoxy)hexane (reactive oxygen: 10.25%, 1 hour half-life temperature: 140° C.), di-tert-amyl peroxide (reactive oxygen: 8.81%, 1 hour half-life temperature: 143° C.), di(tert-butyl) peroxide (reactive oxygen: 10.78%, 1 hour half-life temperature: 149° C.), and cumene hydroperoxide(reactive oxygen: 9.14%, 1 hour half-life temperature: 188° C.). A preferred combination is 1,4 di-tert-butylperoxyisopropyl benzene and cumene hydroperoxide, the amount is adjusted according to the mixing ratio of the resin, and a cured glass with better glass transition temperature and rigidity is generated.

In addition, a resin mixture of the present disclosure can be used to improve interface affinity between the inorganic powder by adding a coupling agent. The coupling agent may be directly added to the resin mixture, or the inorganic powder may be previously treated with the coupling agent to prepare the resin mixture of the present disclosure.

The form of the present disclosure includes the above-described thermosetting resin composition, and the prepreg and cured product formed therefrom. The prepreg is a composite reinforcing material impregnated with a resin mixture at a normal temperature of 15 to 40° C. under an impregnation process, and is further obtained after a drying process at a temperature of 100 to 140° C.

The prepreg of the present disclosure includes 10% to 50% by weight of the reinforcing material and 50% to 90% by weight of the impregnated resin mixture. The reinforcing material is selected from glass cloth, non-woven glass cloth, organic fiber cloth, non-woven organic fiber cloth, paper, non-woven liquid crystal polymer cloth, synthetic fiber cloth, carbon fiber cloth, PP cloth, PTFE cloth and non-woven cloth.

The prepreg composition described above can be applied to a semi-cured film for a printed circuit board, a cured sheet, a copper foil substrate pressed with a copper foil after being impregnated with a glass fiber cloth, and a printed circuit board made of the copper foil substrate. Since the composition contains the above-mentioned interlaced thermosetting polyphenylene ether resin, the characteristics after curing can be characterized by high dielectric constant, low dielectric loss, high glass transition temperature, high heat resistance and high flame resistance, and fully exhibits advantages of the thermosetting polyphenylene ether resin which can reach the specifications of high-order printed circuit boards.

The cured product of the prepreg of the present disclosure can form the copper foil substrate by bonding the copper foil up and down, and is suitable for forming a high frequency circuit substrate. The method for preparing the copper foil substrate can be continuous and automatic, including stacking one or more layers of the prepreg layer, placing a 35 μm thick copper foil on the uppermost and lowermost portions at a pressure of 25 kg/cm² and a temperature at 85° C., keeping the temperature of 85° C. for 20 minutes, increasing the temperature to 150° C. to 190° C. at a heating rate of 3° C./min, keeping the temperature constant for 120 minutes, and then slowly cooling to 130° C. to obtain a copper foil substrate having a thickness of 0.8 mm or more.

The copper foil substrate has the characteristics of high dielectric constant, low dielectric loss, high Tg, high heat resistance, high flame resistance and low water absorption due to the composition of the interlaced thermosetting polyphenylene ether resin described above and fully exhibits advantages of the thermosetting polyphenylene ether resin which can reach the specifications of high-order printed circuit boards.

The following embodiments and comparative examples are given to illustrate the effects of the present disclosure, but the present disclosure is not limited thereto.

The copper foil substrates of the embodiments and comparative examples are evaluated for physical properties according to the following methods:
1. Glass transition temperature (° C.): Tested by a dynamic mechanical analyzer (DMA).
2. Water absorption rate (%): The sample is heated at temperature 120° C. and in a 2 atm pressure cooker for 120 minutes, and the amount of change in weight before and after heating is calculated.
3. 288° C. solder heat resistance (seconds): The sample is heated at temperature 120° C. and in a 2 atm pressure cooker for 120 minutes and then immersed in a 288° C. soldering furnace to record the time required for popcorn delamination of the sample.
4. Peel strength of copper foil (lb/in): Test a peel strength between the copper foil and a circuit carrier.
5. Dielectric constant Dk (10 GHz): The dielectric constant Dk at a frequency of 10 G Hz is tested with a dielectric analyzer HP Agilent E4991A.
6. Dielectric Loss Df (10 GHz): The dielectric loss Df at a frequency of 10 G Hz is tested with a dielectric analyzer HP Agilent E4991A.
7. Polyphenylene ether resin molecular weight test: a quantitative polyphenylene ether resin is dissolved in THF solvent to prepare a 1% solution by weight, and the solution is heated until clarified. The solution is then subjected to GPC (gel permeation chromatography) analysis, and the characteristic front area is calculated. An analytical calibration line is multi-point calibration with polystyrene standards of different molecular weights. After establishing the calibration curve, the molecular weight data can be obtained.
8. Hydroxyl value test: A pyridine solution of 25 vol. % anhydrous acetic anhydride is prepared for an acetylation reagent. Several grams of a sample to be tested and 5 ml of the acetylation reagent are finely weighed, after mixing and heating to completely dissolve the sample, phenolphthalein is added as an indicator and calibrated with a 0.5 N potassium hydroxide ethanol solution.
9. Rigidity: Tested by the Dynamic Mechanical Analyzer (DMA) and represented by a G′ value (storage modulus, GPa) at a temperature of 50° C.
10. Glue-filling property: 6 sheets of electronic grade fiberglass cloth with 1080 specification and resin content (RC) of 70% are pressed with thick copper circuit board. After pressing, it is checked by slicing to see whether the line is completely filled.
11. Cutting property: The prepreg is cut by a panel cutter to judge whether the edge can be completely cut and whether the edge is intact.

### Embodiments 1 to 9, Comparative Examples 1 to 6

The resin composition shown in Table 2 is mixed with toluene to form a varnish of a thermosetting resin composition, and the varnish is impregnated at room temperature with NAN YA fiberglass cloth (NAN YA Plastics Corporation, model number 7628). After drying at 110° C. (impregnation machine) for several minutes, a prepreg with a resin content of 43% by weight is obtained. Finally, four prepreg layers are stacked between two 35 μm thick copper foils at a pressure of 25 kg/cm² and a temperature of 85° C. for 20 minutes, and then are heated to the temperature of 185° C. at a heating rate of 3° C./min and maintained for 120 minutes, and then slowly cooled to 130° C. to obtain a copper foil substrate having a thickness of 0.8 mm or more.

The physical properties of the copper foil substrate are tested, and the results are shown in Table 2.

In conclusion, the circuit boards of Embodiments 1 to 9 have excellent dielectric constant (Dk) and dielectric loss (Df), the dielectric constant can be up to 10.5, the dielectric loss is less than 0.0030, and the glass transition temperature (Tg) is also higher than 200° C. In addition, other physical properties including peel strength of copper foil, water absorption, 288° C. solder heat resistance, and flame resistance, also maintain good characteristics, especially prepreg cutting performance.

In comparative example 1, the TiO₂ ceramic powder having a particle diameter of 0.05 μm is adopted. Since a specific surface area is too large, the dielectric loss cannot be lowered, and water vapor OH group in the environment is easily adsorbed, resulting in poor water absorption and heat resistance. In comparative example 2, alumina powder (80 μm) with large particle diameter is adopted, which has poor dielectric uniformity, high dielectric loss, large particle diameter, and NG line glue-filling.

In embodiments 1 to 5, different ceramic powders are adopted, and the particle diameter is moderate. An addition of 50% by weight can increase the dielectric constant, and the dielectric loss is less than 0.003. The line glue-filling property and heat resistance can be confirmed, and the Tg can be maintained above 200° C.

In embodiments 6 to 8, the use of different ceramic powders and adjustment of the addition ratio can achieve the purpose of controlling Dk and Df, the line glue-filling property and heat resistance can be confirmed, and the Tg can be maintained above 200° C.

In embodiment 9 only SiO₂ is adopted in the formulation. Dk is 3.57, and Df is less than 0.003. It can be seen that the addition of other ceramic powder can further improve the electrical properties of the sheet.

In comparative examples 3-4, the solid content of the ceramic powder is increased to 75% by weight, and the physical properties of the sheet are affected, resulting in a low glass transition temperature (Tg) after curing, poor heat resistance, low peel strength of the substrate, high water absorption rate, and bad line glue-filling property.

In comparative example 5, the addition of the ceramic powder to 25% by weight does not effectively increase the dielectric constant, and the dielectric constant is even lower than that of the formulation with 50% by weight of SiO₂ added. Therefore, in order to effectively increase the dielectric constant, the suitable addition ratio of the ceramic powder is 30% to 70% by weight.

In comparative example 6, the addition of TiO₂ having a purity of 98.9% increases the dielectric loss to 0.0048. Therefore the purity is found to have a great influence on a high-frequency electrical property, and preferably the purity is more than 99.1%.

TABLE 2
Embodiment Prepreg Formulation and property of board

| Composition | | Embodiment | | | | | | | | |
|---|---|---|---|---|---|---|---|---|---|---|
| (wt %) | | 1 | 2 | 3 | 4 | 5 | 6 | 7 | 8 | 9 |
| Polyphen- | PPE-A | 15 | 15 | 15 | 15 | 15 | 15 | 20 | 9 | 15 |
| ylene | (styryl | | | | | | | | | |
| ether | group at | | | | | | | | | |
| | the end)¹ | | | | | | | | | |
| Resin | PPE-B | 15 | 15 | 15 | 15 | 15 | 15 | 20 | 9 | 15 |
| | (acrylic | | | | | | | | | |
| | group at | | | | | | | | | |
| | the end)² | | | | | | | | | |
| | Hydroxyl | 0.01 | 0.01 | 0.01 | 0.01 | 0.01 | 0.01 | 0.01 | 0.01 | 0.01 |
| | value³ | | | | | | | | | |
| | Molecular | 2564 | 2564 | 2564 | 2564 | 2564 | 2564 | 2564 | 2564 | 2564 |
| | weight of | | | | | | | | | |
| | polyphen- | | | | | | | | | |
| | ylene | | | | | | | | | |
| | ether⁴ | | | | | | | | | |
| Polybutadiene resin | | — | — | — | — | — | — | — | — | — |
| crosslinking | TAIC | 8 | 8 | 8 | 8 | 8 | 8 | 15 | 6 | 8 |
| agent | | | | | | | | | | |
| flame | OP-935⁵ | 4 | 4 | 4 | 4 | 4 | 4 | 5 | 2 | 4 |
| retardant | (structural | | | | | | | | | |
| | formula F) | | | | | | | | | |
| | DOPO | 7 | 7 | 7 | 7 | 7 | 7 | 9 | 3 | 7 |
| | flame | | | | | | | | | |
| | retardant⁶ | | | | | | | | | |
| | (structural | | | | | | | | | |
| | formula E) | | | | | | | | | |
| Ceramic | SiO₂ | 0 | 0 | 0 | 0 | 0 | 0 | 0 | 0 | 50 |
| powder | (d50 = | | | | | | | | | |
| | 8 um) | | | | | | | | | |
| | Purity: | | | | | | | | | |
| | 99.9% | | | | | | | | | |
| | Tio₂ | 50 | 0 | 0 | 0 | 0 | 40 | 30 | 70 | 0 |
| | (D50 = | | | | | | | | | |
| | 2 um) | | | | | | | | | |
| | Purity: | | | | | | | | | |
| | 99.9% | | | | | | | | | |
| | Tio₂ (D50 = | 0 | 0 | 0 | 0 | 0 | 0 | 0 | 0 | 0 |
| | 0.05 um) | | | | | | | | | |
| | Purity: | | | | | | | | | |
| | 99.9% | | | | | | | | | |
| | Strontium | 0 | 50 | 0 | 0 | 0 | 0 | 0 | 0 | 0 |
| | titanate | | | | | | | | | |
| | (D50 = | | | | | | | | | |
| | 4 um) | | | | | | | | | |
| | Purity: | | | | | | | | | |
| | 99.9% | | | | | | | | | |
| | Barium | 0 | 0 | 50 | 0 | 0 | 0 | 0 | 0 | 0 |
| | titanate | | | | | | | | | |
| | (D50 = | | | | | | | | | |
| | 5 um) | | | | | | | | | |
| | Purity: | | | | | | | | | |
| | 99.9% | | | | | | | | | |
| | Calcium | 0 | 0 | 0 | 50 | 0 | 0 | 0 | 0 | 0 |
| | titanate | | | | | | | | | |
| | (D50 = | | | | | | | | | |
| | 4 um) | | | | | | | | | |
| | Purity: | | | | | | | | | |
| | 99.9% | | | | | | | | | |
| | Aluminium | 0 | 0 | 0 | 0 | 50 | 10 | 0 | 0 | 0 |
| | oxide | | | | | | | | | |
| | (D50 = | | | | | | | | | |
| | 10 um) | | | | | | | | | |
| | Purity: | | | | | | | | | |
| | 99.9% | | | | | | | | | |
| | Aluminium | 0 | 0 | 0 | 0 | 0 | 0 | 0 | 0 | 0 |
| | oxide | | | | | | | | | |
| | (D50 = | | | | | | | | | |
| | 80 um) | | | | | | | | | |
| | Purity: | | | | | | | | | |
| | 99.9% | | | | | | | | | |
| | Tio₂ | 0 | 0 | 0 | 0 | 0 | 0 | 0 | 0 | 0 |
| | (D50 = | | | | | | | | | |
| | 2 um) | | | | | | | | | |
| | Purity: | | | | | | | | | |
| | 98.9% | | | | | | | | | |
| | Total | 50 | 50 | 50 | 50 | 50 | 50 | 30 | 70 | 50 |
| Initiator | 1,4-tert- | 0.5 | 0.5 | 0.5 | 0.5 | 0.5 | 0.5 | 0.5 | 0.5 | 0.5 |
| | butyl- | | | | | | | | | |
| | peroxy- | | | | | | | | | |
| | isopropyl- | | | | | | | | | |
| | benzene | | | | | | | | | |
| | Cumene | 0.5 | 0.5 | 0.5 | 0.5 | 0.5 | 05 | 0.5 | 0.5 | 0.5 |
| | hydroper- | | | | | | | | | |
| | oxide | | | | | | | | | |
| Glass transition | | 208 | 218 | 221 | 210 | 211 | 232 | 219 | 220 | 221 |
| temperature(° C.) | | | | | | | | | | |
| (DMA)⁷ | | | | | | | | | | |
| Water absorption | | 0.04 | 0.02 | 0.0 | 0.03 | 0.03 | 0.02 | 0.02 | 0.02 | 0.03 |
| rate(%)⁸ | | | | | | | | | | |
| 288° C. resistant | | >600 | >600 | >600 | >600 | >600 | >600 | >600 | >600 | >600 |
| solder with heat | | | | | | | | | | |
| resistance (sec)⁹ | | | | | | | | | | |
| Peel strength of | | 5.22 | 5.68 | 5.86 | 5.68 | 5.75 | 5.95 | 5.88 | 5.75 | 5.85 |
| copper foil (lb/in) | | | | | | | | | | |
| Rigidity (modulus at | | 14.8 | 14.5 | 15.9 | 14.6 | 14.7 | 13.8 | 10.9. | 17.2 | 15.2 |
| 50° C., Gpa)¹⁰ | | | | | | | | | | |
| Board¹¹ | Dielectric | 8.2 | 10.3 | 10.5 | 10.3 | 6.1 | 7.2 | 4.1 | 10.2 | 3.57 |
| | constant | | | | | | | | | |
| | dk | | | | | | | | | |
| | Dielectric | 2.7 | 2.8 | 3.0 | 2.4 | 2.2 | 2.5 | 2.3 | 2.8 | 2.5 |
| | loss Df | | | | | | | | | |
| | (×10⁻³) | | | | | | | | | |

| | | | | | | | | | |
|---|---|---|---|---|---|---|---|---|---|
| Flame resistance | V0 | V0 | V0 | V0 | V0 | V0 | V0 | V0 | V0 |
| (UL-94) | | | | | | | | | |
| 2 OZ thick copper | ○ | ○ | ○ | ○ | ○ | ○ | ○ | ○ | ○ |
| line glue-filling¹² | | | | | | | | | |
| Prepreg cutability¹³ | ○ | ○ | ○ | ○ | ○ | ○ | ○ | ○ | ○ |

| Composition | | Comparative example | | | | | |
|---|---|---|---|---|---|---|---|
| (wt %) | | 1 | 2 | 3 | 4 | 5 | 6 |
| Polyphen- | PPE-A | 15 | 15 | 7 | 7 | 20 | 15 |
| ylene | (styryl | | | | | | |
| ether | group at | | | | | | |
| | the end)¹ | | | | | | |
| Resin | PPE-B | 15 | 15 | 7 | 7 | 20 | 15 |
| | (acrylic | | | | | | |
| | group at | | | | | | |
| | the end)² | | | | | | |
| | Hydroxyl | 0.01 | 0.01 | 0.01 | 0.01 | 0.01 | 0.01 |
| | value³ | | | | | | |
| | Molecular | 2564 | 2564 | 2564 | 2564 | 2564 | 2564 |
| | weight of | | | | | | |
| | polyphen- | | | | | | |
| | ylene | | | | | | |
| | ether⁴ | | | | | | |
| Polybutadiene resin | | — | — | — | — | — | — |
| crosslinking | TAIC | 9.2 | 9.2 | 5 | 5 | 20 | 8 |
| agent | | | | | | | |
| flame | OP-935⁵ | 4 | 4 | 2 | 2 | 5 | 4 |
| retardant | (structural | | | | | | |
| | formula F) | | | | | | |
| | DOPO | 7 | 7 | 3 | 3 | 9 | 7 |
| | flame | | | | | | |
| | retardant⁶ | | | | | | |
| | (structural | | | | | | |
| | formula E) | | | | | | |
| Ceramic | SiO₂ | 0 | 0 | 0 | 0 | 0 | 0 |
| powder | (d50 = | | | | | | |
| | 8 um) | | | | | | |
| | Purity: | | | | | | |
| | 99.9% | | | | | | |
| | Tio₂ | 0 | 0 | 75 | 0 | 25 | 0 |
| | (D50 = | | | | | | |
| | 2 um) | | | | | | |
| | Purity: | | | | | | |
| | 99.9% | | | | | | |
| | Tio₂ (D50 = | 50 | 0 | 0 | 0 | 0 | 0 |
| | 0.05 um) | | | | | | |
| | Purity: | | | | | | |
| | 99.9% | | | | | | |
| | Strontium | 0 | 0 | 0 | 75 | 0 | 0 |
| | titanate | | | | | | |
| | (D50 = | | | | | | |
| | 4 um) | | | | | | |
| | Purity: | | | | | | |
| | 99.9% | | | | | | |
| | Barium | 0 | 0 | 0 | 0 | 0 | 0 |
| | titanate | | | | | | |
| | (D50 = | | | | | | |
| | 5 um) | | | | | | |
| | Purity: | | | | | | |
| | 99.9% | | | | | | |
| | Calcium | 0 | 0 | 0 | 0 | 0 | 0 |
| | titanate | | | | | | |
| | (D50 = | | | | | | |
| | 4 um) | | | | | | |
| | Purity: | | | | | | |
| | 99.9% | | | | | | |
| | Aluminium | 0 | 0 | 0 | 0 | 0 | 0 |
| | oxide | | | | | | |
| | (D50 = | | | | | | |
| | 10 um) | | | | | | |
| | Purity: | | | | | | |
| | 99.9% | | | | | | |
| | Aluminium | 0 | 50 | 0 | 0 | 0 | 0 |
| | oxide | | | | | | |
| | (D50 = | | | | | | |
| | 80 um) | | | | | | |
| | Purity: | | | | | | |
| | 99.9% | | | | | | |
| | Tio₂ | 0 | 0 | 0 | 0 | 0 | 50 |
| | (D50 = | | | | | | |
| | 2 um) | | | | | | |
| | Purity: | | | | | | |
| | 98.9% | | | | | | |
| | Total | 50 | 50 | 75 | 75 | 25 | 0 |
| Initiator | 1,4-tert- | 0.5 | 0.5 | 0.5 | 0.5 | 0.5 | 0.5 |
| | butyl- | | | | | | |
| | peroxy- | | | | | | |
| | isopropyl- | | | | | | |
| | benzene | | | | | | |
| | Cumene | 0.5 | 0.5 | 0.5 | 0.5 | 0.5 | 0.5 |
| | hydroper- | | | | | | |
| | oxide | | | | | | |
| Glass transition | | 198 | 183 | 194 | 198 | 224 | 210 |
| temperature(° C.) | | | | | | | |
| (DMA)⁷ | | | | | | | |
| Water absorption | | 0.10 | 0.11 | 0.15 | 0.16 | 0.02 | 0.04 |
| rate(%)⁸ | | | | | | | |
| 288° C. resistant | | 214 | 202 | 102 | 152 | >600 | >600 |
| solder with heat | | | | | | | |
| resistance (sec)⁹ | | | | | | | |
| Peel strength of | | 3.85 | 5.85 | 3.84 | 4.05 | 6.51 | 5.32 |
| copper foil (lb/in) | | | | | | | |
| Rigidity (modulus at | | 12.5 | 8.8 | 7.5 | 8.6 | 7.5 | 14.6 |
| 50° C., Gpa)¹⁰ | | | | | | | |
| Board¹¹ | Dielectric | 8.6 | 5.56 | 11.5 | 10.8 | 3.12 | 9.1 |
| | constant | | | | | | |
| | dk | | | | | | |
| | Dielectric | 5.2 | 4.8 | 2.9 | 3.5 | 2.0 | 4.8 |
| | loss | | | | | | |
| | DF(x10⁻³) | | | | | | |

| | | | | | | |
|---|---|---|---|---|---|---|
| Flame resistance | V0 | V0 | V0 | V0 | V0 | V0 |
| (UL-94) | | | | | | |
| 2 OZ thick copper | NG | NG | NG | NG | OK | OK |
| line glue-filling¹² | | | | | | |
| Prepreg cutability¹³ | NG | NG | NG | NG | OK | OK |

P.S.
¹Styrene type polyphenylene ether resin structure having a styryl group at the end: 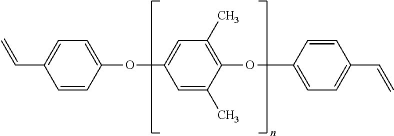
²Acrylic type polyphenylene ether resin structure with an acrylic group at the end: 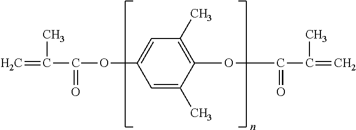
³Hydroxyl value (mgKOH/g): A pyridine solution of 25 vol.% anhydrous acetic anhydride for preparing an acetylation reagent. A precision scale mixes several grams of a sample to be tested and 5 ml of the acetylation reagent, after heating to completely dissolve the sample, phenolphthalein is added as an indicator and calibrated with a 0.5 N potassium hydroxide ethanol solution.
⁴Molecular weight test: A quantitative polyphenylene ether resin is dissolved in THF solvent to prepare a 1 % solution by weight, and the solution is heated until clarified. The solution is then subjected to GPC (gel permeation chromatography) analysis, and the characteristic front area is calculated. An analytical calibration line is multi-point calibration with polystyrene standards of different molecular weights. After establishing the calibration curve, the molecular weight data can be obtained.
⁵OP935 structure: 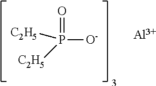
structural formula (F).
⁶DOPO type flame retardant 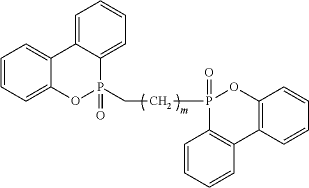
structural formula (E); and m = 2.
⁷Using a dynamic mechanical analyzer (DMA) to test, a tan δ value is the maximum temperature (wave peak).
⁸The sample is heated at temperature 120° C. and in a 2 atm pressure cooker for 120 minutes to calculate the difference in weight before and after.
⁹The sample is heated at temperature 120° C. and in a 2 atm pressure cooker for 120 minutes and then immersed in a 288° C. soldering furnace to record the time required for popcorn delamination of the sample, , >600 means higher than 600 seconds.
10Using a dynamic mechanical analyzer (DMA) and represented by a G′ value (storage modulus, GPa) at a temperature of 100° C.
¹¹Substrate: A composition containing a cured fiberglass cloth.
¹²6 sheets of electronic grade fiberglass cloth with 1080 specification and resin content (RC) of 70% are pressed with thick copper circuit board. After pressing, check whether the line is completely filled by slicing.
¹³Prepreg cutting property: ○: cutting is normal; Δ: not easy to cut; X: unable to cut.

The foregoing description of the exemplary embodiments of the disclosure has been presented only for the purposes of illustration and description and is not intended to be exhaustive or to limit the disclosure to the precise forms disclosed. Many modifications and variations are possible in light of the above teaching.

The embodiments were chosen and described in order to explain the principles of the disclosure and their practical application so as to enable others skilled in the art to utilize the disclosure and various embodiments and with various modifications as are suited to the particular use contemplated. Alternative embodiments will become apparent to those skilled in the art to which the present disclosure pertains without departing from its spirit and scope.

What is claimed is:

1. A thermosetting re sin composition comprising:
(a) a thermosetting polyphenylene ether resin which accounts for 15% to 35% by weight of a solid content of the thermosetting resin composition, wherein the thermosetting polyphenylene ether resin includes a styrene type polyphenylene ether resin and an acrylic type polyphenylene ether resin, and wherein the ratio of the styrene type polyphenylene ether resin to the acrylic type polyphenylene ether resin is from 1:0.5 to 1:1.5;
(b) a ceramic powder which accounts for 30% to 70% by weight of the solid content of the thermosetting resin composition;
(c) a flame retardant which accounts for 5% to 15% by weight of the solid content of the thermosetting resin composition;
(d) a crosslinking agent which accounts for 5% to 20% by weight of the solid content of the thermosetting resin composition; and
(e) a composite crosslinking initiator which accounts for 0.1% to 3% by weight of the solid content of the thermosetting resin composition.

2. The thermosetting resin composition according to claim 1, wherein the thermosetting polyphenylene ether resin composition includes a styrene type polyphenylene ether having a styryl group at the end and an acrylic type polyphenylene ether having an acrylic group at the end;
wherein the styrene type polyphenylene ether is represented by structural formula (A): 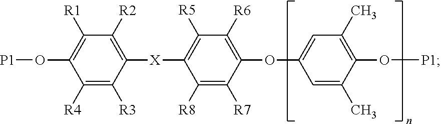
wherein R1 to R8 are independently selected from the group consisting of allyl, hydrogen and C1-C6 alkyl;
X is selected from the group consisting of oxygen atoms: 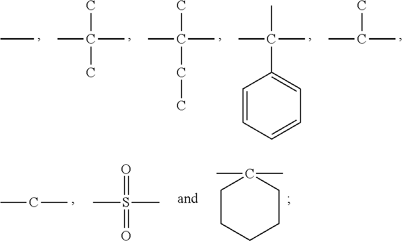
wherein P1 is a styrene group 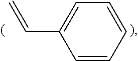
and n is an integer of 1 to 99;
wherein the acrylic type polyphenylene ether is represented by the structural formula (B): 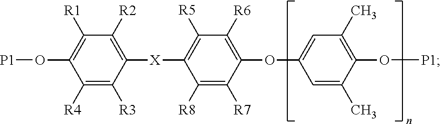
wherein R1 to R8 are independently selected from the group consisting of allyl, hydrogen and C1-C6 alkyl;
X is selected from the group consisting of oxygen atoms, 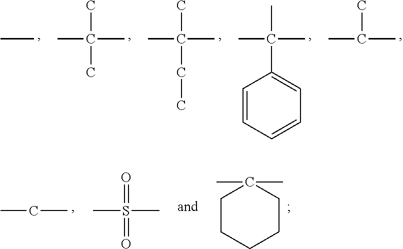
wherein P2 is 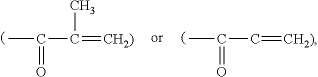
and n is an integer of 1 to 99.

3. The thermosetting resin composition according to claim 1, wherein the thermosetting polyphenylene ether resin has a hydroxyl value of 0.001 to 3.0 mgKOH/g.

4. The thermosetting resin composition according to claim 1, wherein the ceramic powder is selected from a group consisting of: titanium dioxide, aluminum oxide, barium titanate, calcium titanate, magnesium titanate, silicon dioxide and mixtures thereof.

5. The thermosetting resin composition according to claim 4, wherein the ceramic powder has a particle diameter between 1 μm and 40 μm.

6. The thermosetting resin composition according to claim 4, wherein the ceramic powder has a spherical shape.

7. The thermosetting resin composition according to claim 4, wherein the purity of the ceramic powder is 99.1% or more.

8. The thermosetting resin composition according to claim 1, wherein the flame retardant is a bromine-based flame retardant, and the bromine-based flame retardant is selected from one or any combination of decabromodiphenylethane and 1,2-bis(tetrabromophthalimide)ethane.

9. The thermosetting resin composition according to claim 1, wherein the flame retardant is a phosphorus-based flame retardant, and the phosphorus-based flame retardant is selected from the group consisting of: phosphate esters, phosphazenes, ammonium polyphosphates, melamine phosphates, melamine cyanurates, aluminum hypophosphite containing flame retardant, 9,10-dihydro-9-oxo-10-phosphaphenanthrene-10-oxide (DOPO) containing flame retardant and combination thereof.

10. The thermosetting resin composition according to claim 9, wherein the aluminum hypophosphite containing flame retardant is:

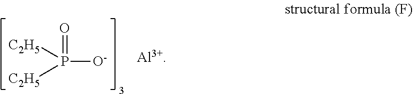

11. The thermosetting resin composition according to claim 9, wherein the DOPO containing flame retardant is selected from one or any combination of: 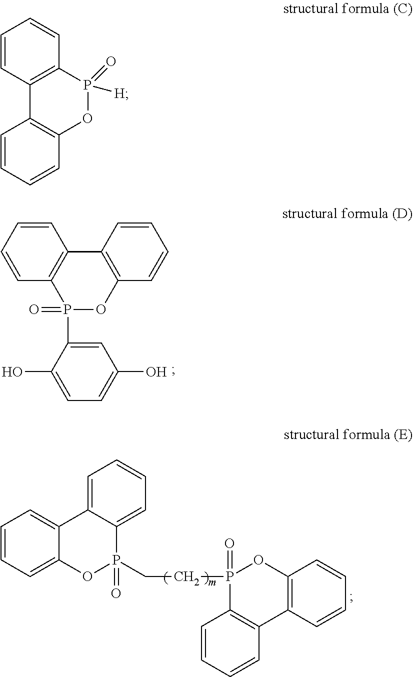
and m is an integer of 1 to 4.

12. The thermosetting resin composition according to claim 1, wherein the composite crosslinking initiator is 1,4 di-tert-butylperoxyisopropyl benzene, cumene hydroperoxide or a combination thereof.

13. A printed circuit board comprising an insulating layer made of a thermosetting resin composition, and the thermosetting resin composition including:
(a) a thermosetting polyphenylene ether resin which accounts for 15% to 35% by weight of a solid content of the thermosetting resin composition, wherein the thermosetting polyphenylene ether resin includes a styrene type polyphenylene ether resin and an acrylic type polyphenylene ether resin, and wherein the ratio of the styrene type polyphenylene ether resin to the acrylic type polyphenylene ether resin is from 1:0.5 to 1:1.5;
(b) a ceramic powder which accounts for 30% to 70% by weight of the solid content of the thermosetting resin composition;
(c) a flame retardant which accounts for 5% to 15% by weight of the solid content of the thermosetting resin composition;
(d) a crosslinking agent which accounts for 5% to 20% by weight of the solid content of the thermosetting resin composition; and
(e) a composite crosslinking initiator which accounts for 0.1% to 3% by weight of the solid content of the thermosetting resin composition.

14. The thermosetting resin composition according to claim 13, wherein the thermosetting polyphenylene ether resin composition includes a styrene type polyphenylene ether having a styryl group at the end and an acrylic type polyphenylene ether having an acrylic group at the end;
wherein the styrene type polyphenylene ether is represented by structural formula (A): 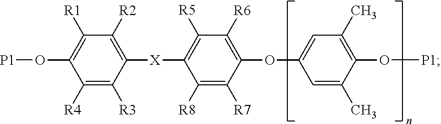
wherein R1 to R8 are independently selected from the group consisting of allyl, hydrogen and C1-C6 alkyl;
X is selected from the group consisting of oxygen atoms: 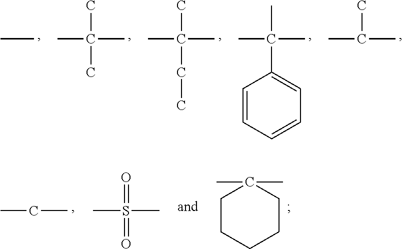
wherein P1 is a styrene group 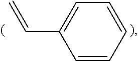
and n is an integer of 1 to 99;
wherein the acrylic type polyphenylene ether is represented by the structural formula (B): 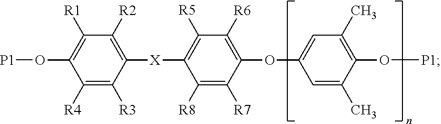
wherein R1 to R8 are independently selected from the group consisting of allyl, hydrogen and C1-C6 alkyl;
X is selected from the group consisting of oxygen atoms, 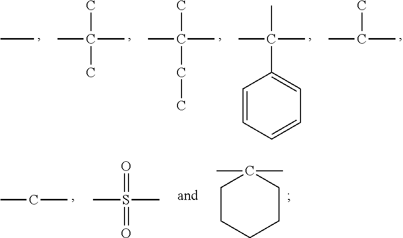
wherein P2 is 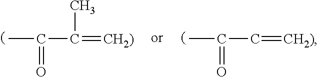
and n is an integer of 1 to 99.
